(19) United States
(12) Patent Application Publication
(10) Pub. No.: US 2015/0128697 A1
(43) Pub. Date: May 14, 2015

(54) MEMS DEVICE PACKAGE

(71) Applicant: SAMSUNG ELECTRO-MECHANICS CO., LTD., Suwon-Si (KR)

(72) Inventors: Jong Man Kim, Suwon-si (KR); Kyu Hwan Oh, Suwon-Si (KR); Soon Gyu Yim, Suwon-Si (KR)

(73) Assignee: SAMSUNG ELECTRO-MECHANICS CO., LTD., Suwon-Si (KR)

(21) Appl. No.: 14/263,642

(22) Filed: Apr. 28, 2014

(30) Foreign Application Priority Data
Nov. 12, 2013 (KR) 10-2013-0136847

(51) Int. Cl. G01D 11/10; B81B 7/00; G01D 11/24

(52) U.S. Cl. CPC G01D 11/10; G01D 11/245; B81B 7/0058
USPC 73/430; 73/431

(57) ABSTRACT

Disclosed herein is a MEMS device package including a hollow tubular part, a top cap formed to cover a top opening of the tubular part, a bottom cap formed to cover a bottom opening of the tubular part, and a sensor device equipped in a cavity of the tubular part. The MEMS device can use tubular parts having a variety of cross sections and also enhance an impact resistance by inserting a damper into the tubular part.

### CROSS REFERENCE TO RELATED APPLICATION

This application claims the benefit of Korean Patent Application No. 10-2013-0136847, filed on Nov. 12, 2013, entitled “MEMS Device Package,” which is hereby incorporated by reference in its entirety into this application.

### BACKGROUND OF THE INVENTION

1. Technical Field

The present invention relates to a MEMS device package.

2. Description of the Related Art

Microelectromechanical system (MEMS) devices are devices in which functional devices such as a sensor or switch are integrated using microfabrication technologies in order to implement a three-dimensional mobile structure. As widely known, MEMS devices may be fabricated by applying semiconductor forming technologies, thereby enabling small size and high performance and thus allowing small mounting dimensions and saving power consumption.

MEMS devices have sizes in the range from one to hundreds of microns or more. Thus the sizes of housings for protecting the MEMS devices also tend to decrease gradually. In general, in a case where the MEMS device package having an internal sensor, which is used to detect an external movement, mounted thereon is fabricated in a small size, an impact from the outside may induce its housing to be excessively transformed and thus the internal sensor may generate abnormal signals.

Patent document 1 describes a technology for detecting a rotational angular velocity, which is formed to include a spring part for elastically supporting a sensor part in the housing such that ease of assembly and fabrication may be facilitated. The spring part elastically supports the sensor part spaced from the housing at a certain interval and also assists the sensor part in being connected to the wiring of the circuit board.

That is, patent document 1 places emphasis on securing a mechanical motion space for detecting an external fine movement, but actually may not secure an environment that is stable against an external force.

### PRIOR ART DOCUMENT

(Patent Document 1) Korea Patent Laid-Open Publication No. 10-2004-0050720

### SUMMARY OF THE INVENTION

The present invention has been made in an effort to provide a MEMS device package formed to have a driving space for performing a mechanical operation according to an external fine movement and stably protect internal mounted components against an external impact.

According to a first preferred embodiment of the present invention, there is provided a MEMS device package including: a hollow tubular part; a top cap formed to cover a top opening of the tubular part; a bottom cap formed to cover a bottom opening of the tubular part; and a sensor device equipped in a cavity of the tubular part.

The sensor device may be equipped in the tubular part by using a support structure having a plate and an elastic arm, and the support structure may have a pattern for connecting the sensor device and an external controller.

The present invention may be bonded to the tubular part by stacking an adhesive layer on the top and bottom surfaces of the tubular part.

The tubular part may have one or more slits formed along a perimeter thereof.

The one or more slits may be separated at an equal distance along the perimeter of the tubular part.

The slits may pass through from the top surface of the tubular part to bottom surface thereof.

The present invention may have a damper built in the slit, thereby mitigating an external impact.

The damper may be formed to have a shape of an I-beam and inserted into the slit.

Alternatively, the damper may be formed to have a shape of a T-bean and inserted into the top and bottom of the slit.

The damper may be formed of foam, thereby completely filling the slit.

The damper may be formed to have a honeycomb structure.

Optionally, the damper may be curved at the same curvature as the tubular part.

The tubular part according to a first embodiment of the present invention may be a quadrangular tubular part having a quadrangular cross section.

In the first embodiment, the top cap and the bottom cap may be formed to have a shape of a plate and to close a top opening and a bottom opening of the tubular part.

The top cap may have a side part protruding in a vertical direction along a perimeter thereof.

The bottom cap may have a side part protruding in a vertical direction along a perimeter thereof.

The tubular part according to a second embodiment of the present invention may be a circular tubular part having a circular cross section.

In the second embodiment, the top cap and the bottom cap may be formed to have a shape of an arch.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view of a MEMS device package according to a first embodiment of the present invention;

FIG. 2 is an exploded perspective view of the MEMS device package shown in FIG. 1;

FIG. 3 is an exploded perspective view of a MEMS device package having a damper having a different shape from a damper of the MEMS device package according to the first embodiment;

FIG. 4 is a perspective view of a MEMS device package according to a second embodiment of the present invention;

FIG. 5 is an exploded perspective view of the MEMS device package shown in FIG. 4.

FIGS. 6a and 6b are exploded perspective views of a MEMS device package having a circular tubular part having a different type from a circular tubular part of the MEMS device package according to the second embodiment; and

FIGS. 7a and 7b are exploded perspective views of a MEMS device package having a damper having a different shape from a damper of the MEMS device package according to the second embodiment.

### DESCRIPTION OF THE PREFERRED EMBODIMENTS

Hereinafter, a MEMS device package according to the present invention will be described in detail with reference to the accompanying drawings.

Various advantages and features of the present invention and methods accomplishing thereof will become apparent from the following description of embodiments with reference to the accompanying drawings. In the present specification, in adding reference numerals to components shown in each of the accompanying drawings, it is to be noted that like reference numerals designate like or similar components throughout the specification. Further, in the present specification, when a detailed description of the known art related to the present invention obscure the gist of the present invention, the detailed description thereof will be omitted.

The MEMS device package according to the present invention is formed to secure a driving space for relatively moving a sensor device and also improve impact resistance and include a hollow tubular part; a top cap for covering a top opening of the tubular part; a bottom cap for covering a bottom opening of the tubular part; and a sensor device equipped in a cavity of the tubular part. The tubular part may have various cross sectional shapes. A quadrangular tubular part having a quadrangular cross section will be described in detail in the first embodiment, and a circular tubular part having a circular cross section will be described in the second embodiment.

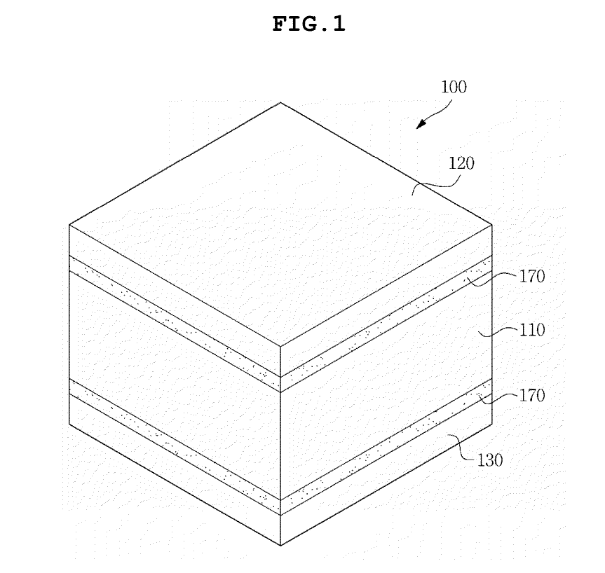

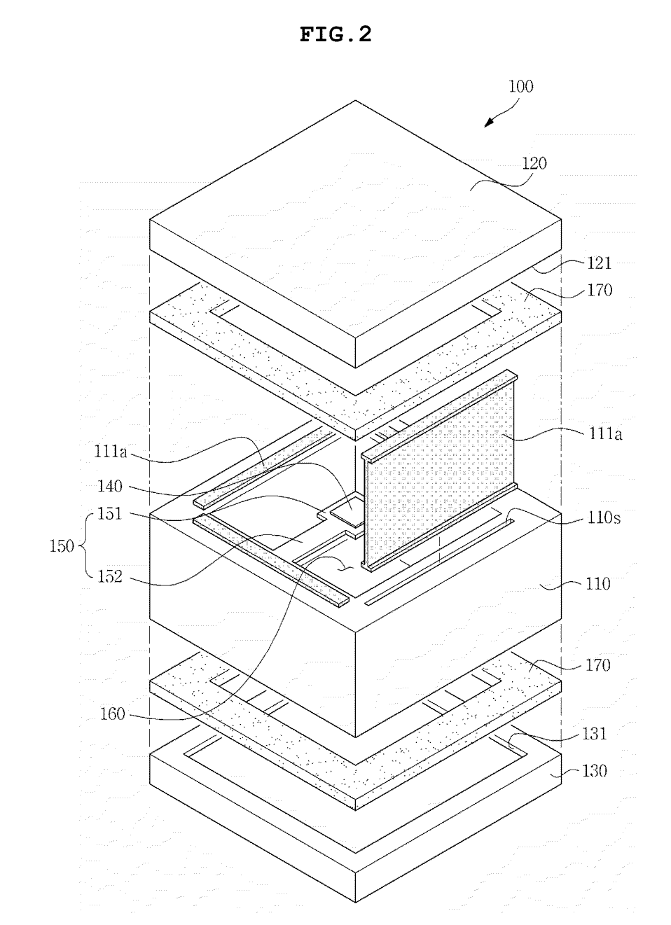

FIGS. 1 and 2 show a MEMS device package according to a first embodiment of the present invention.

As shown, the MEMS device package 100 according to the first embodiment of the present invention is formed to include a quadrangular tubular part 110, a top cap 120, and a bottom cap 130 and have a shape of a hollow box.

A MEMS device package 100 has a support structure 150 disposed across the hollow quadrangular tubular part 110. The support structure 150 is formed to include a plate 151 for assisting the sensor device 140 in being fitly disposed and an elastic arm 152 connecting the plate 151 and an inner side of the quadrangular tubular part 110. The elastic arm 152 may move relatively in order to sensitively respond to a movement external to the MEMS device package 100. Here the movement may be a translational motion and/or a rotational motion.

The support structure 150 may serve as a frame that fixes the sensor device 140 and form a pattern that delivers a driving signal. Additionally, the support structure 150 may supply the driving current to the sensor device 140 and form a pattern that delivers a position sensing signal to a control part (not shown). For the convenience of better understanding a structure of the MEMS device package, in this specification, detailed description of the support structure 150 will be omitted.

Preferably, the quadrangular tubular part 110 has at least one slit 110s formed on each side thereof. As shown, the slits 110s are extended in a length direction of the quadrangular tubular part 110. The quadrangular tubular part 110 has a structure that can mitigate an impact to be applied to a side surface of the MEMS device package 100 of the present invention by inserting a damper 111a into the slit 110s.

Alternatively, the damper 111a has a shape of an I-beam. A top of the damper 111a is disposed on a top surface of the quadrangular tubular part 110, and a bottom of the damper 111a is disposed on a bottom surface of the quadrangular tubular part 110. Since the top and bottom of the damper 111a have a size greater than the slit 110s, the damper 111a may be tightly fixed to the quadrangular tubular part 110. The top and bottom of the damper 111a may be fitly or protrudedly arranged in the top surface and the bottom surface of the quadrangular tubular part 110, thereby mitigating an impact applied to the top cap 120 and/or the bottom cap 130, specifically an impact applied to the top and/or bottom of the MEMS device package 100 of the present invention to prevent the impact from being delivered into the quadrangular tubular part 110.

Here, the damper 111a may be formed of a material, for example, rubber, polymer, or the like, which can absorb an impact applied from the outside of the quadrangular tubular part 110. Furthermore, the damper 111a may be made of foam to sufficiently fill the slit 110s to reduce porosity and maximize an impact-absorbing effect. As necessary, the damper 111a may have a honeycomb structure to become less in weight and enhance non-compressive strength.

As shown, the quadrangular tubular part 110 has openings at the top and the bottom thereof. A plate-shaped top cap 120 is disposed on the top surface of the quadrangular tubular part 110 to cover the top surface of the quadrangular tubular part 110. Correspondingly, a plate-shaped bottom cap 130 is disposed on the bottom surface of the quadrangular tubular part 110 to cover the bottom surface of the quadrangular tubular part 110. That is, the device package 100 has a cavity 160 formed therein surrounded by the top cap 120, the quadrangular tubular part 110, and the bottom cap 130. As described above, the cavity 160 is used as a space for driving the support structure 150.

Alternatively, the plate-shaped top cap 120 and/or bottom cap 130 may have side parts 121 and 131 formed to protrude in a vertical direction along a perimeter thereof, respectively. In assembly, the side parts 121 and 131 of the top and bottom caps 120 and 130 are fitly disposed on the top and bottom surfaces of the quadrangular tubular part 110, respectively.

The side parts 121 and 131 may increase a volume of the cavity 160 of the MEMS device package 100 according to the first embodiment of the present invention, thereby minimizing contact to the inner side of the MEMS device package 100 due to deflection of the support structure 150 which is unexpectedly and abnormally driven.

The MEMS device package 100 has an adhesive layer 170 disposed between the top cap 120 and the top surface of the quadrangular tubular part 110. The adhesive layer 170 assists in bonding between the top cap 120 and the quadrangular tubular part 110 in addition to between the top cap 120 and a top of the damper 111a.

In addition, the MEMS device package 100 has an adhesive layer 170 disposed between the bottom cap 130 and the bottom surface of the quadrangular tubular part 110. The adhesive layer 170 assists in bonding between the bottom cap 130 and the quadrangular tubular part 110 in addition to between the bottom cap 120 and a bottom of the damper 111a.

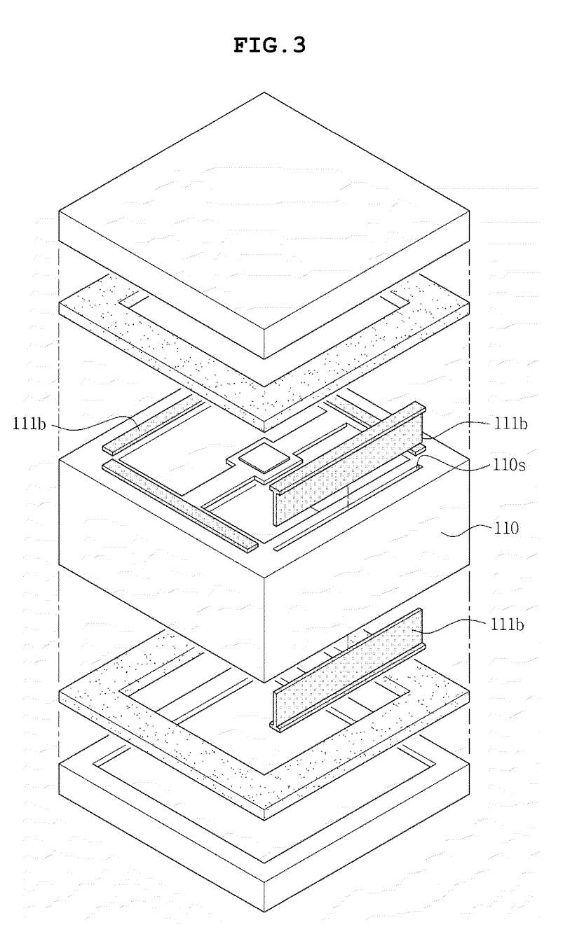

FIG. 3 is an exploded perspective view of a MEMS device package having a damper having a different shape from the damper of the MEMS device package according to the first embodiment. The MEMS device package shown in FIG. 3 has a structure extremely similar to the MEMS device package of the first embodiment, except a structural shape of the damper 111a shown in FIG. 2. Therefore, in order to assist in clear understanding of the present invention, a description of components that are the same as or similar to the above-mentioned components will be omitted.

The quadrangular tubular part 110 of the present invention has at least one slit 110s formed on each side thereof. As shown, the slit 110s extends in a length direction of the quadrangular tubular part 110. The slit 110s may be in communication from the top surface of the quadrangular tubular part 110 to the bottom surface. Alternatively, the slit 110s may be partitioned into separate upper and lower slits. The quadrangular tubular part 110 has a damper 111b inserted into the slit 110s.

Alternatively, the damper 111b is formed to have a shape of a T-beam. One damper 111b may be inserted into the slit 110s formed on the top surface of the quadrangular tubular part 110 while the other damper 111b may be inserted into the slit 110s formed on the bottom surface of the quadrangular tubular part 110.

End parts of the T-beam shaped damper 111b are fitly disposed on the top and bottom surfaces of the quadrangular tubular part 110. This will facilitate insertion into the slit 110s and secure contact to the top or bottom surface.

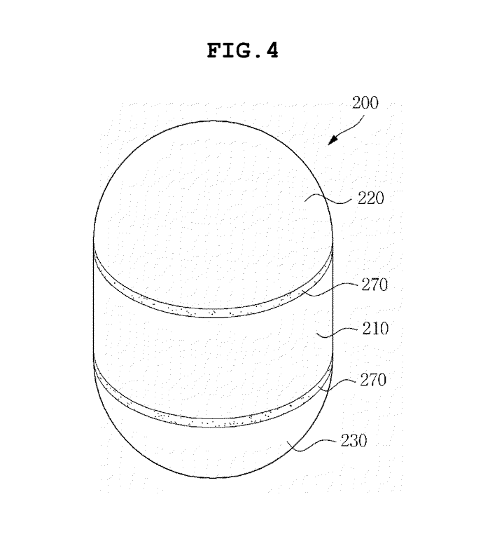

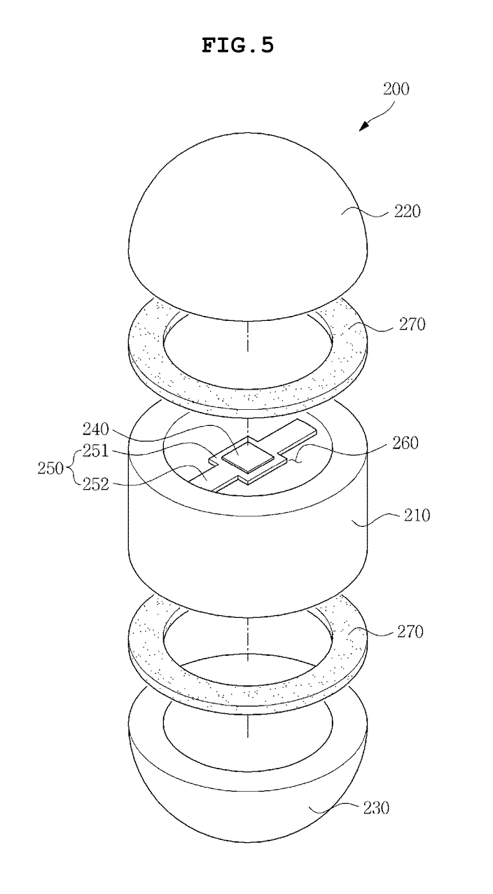

FIGS. 4 and 5 show a MEMS device package according to a second embodiment of the present invention.

As shown, the MEMS device package 200 according to the second embodiment of the present invention is formed to include a circular tubular part 210, a top cap 220, and a bottom cap 230 and have a shape of a hollow capsule. The shape of the capsule is formed by removing edges(or corners) of the shape of the box of the first embodiment to form a circle or ellipse. Accordingly, it is possible to distribute stress focused on the edge parts of the first embodiment. MEMS device package 200 has a support structure 250 disposed across the hollow circular tubular part 210. The support structure 250 is formed to include a plate 251 assisting the sensor device 240 in being fitly disposed and an elastic arm 252 connecting the plate 251 and an inner side of the circular tubular part 210. The elastic arm 252 may move relatively in order to sensitively respond to a movement external to the MEMS device package 200.

As shown, the circular tubular part 210 has openings at the top and the bottom thereof. An arch-shaped top cap 220 is disposed on the top surface of the circular tubular part 110 to cover the top surface of the circular tubular part 210. Correspondingly, an arch-shaped bottom cap 230 is disposed on the bottom surface of the circular tubular part 210 to cover the bottom surface of the circular tubular part 210. That is, the device package 200 has a cavity 260 formed therein surrounded by the top cap 220, the circular tubular part 210, and the bottom cap 230. As described above, the cavity 260 is used as a space for driving the support structure 250.

The MEMS device package 200 according to the second embodiment of the present invention has an adhesive layer 270 disposed between the top cap 220 and the top surface of the circular tubular part 210. The adhesive layer 270 assists in bonding between the top cap 220 and the circular tubular part 210. The MEMS device package 200 has an adhesive layer 170 disposed between the bottom cap 230 and the bottom surface of the circular tubular part 210. The adhesive layer 270 assists in bonding between the bottom cap 230 and the circular tubular part 210.

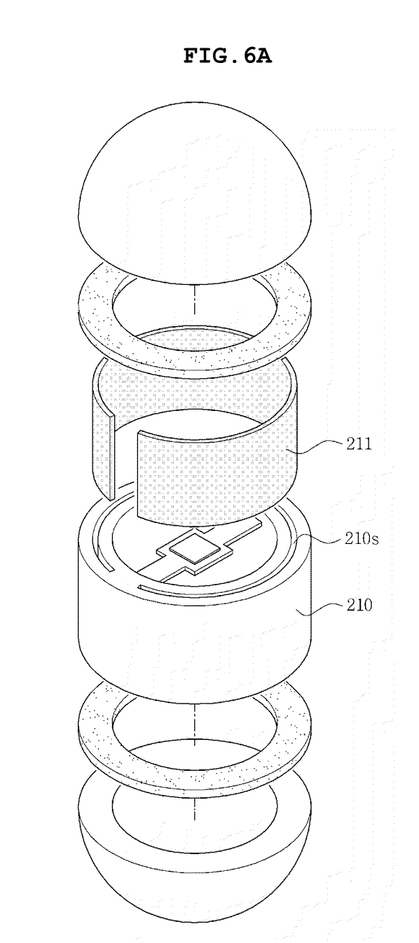

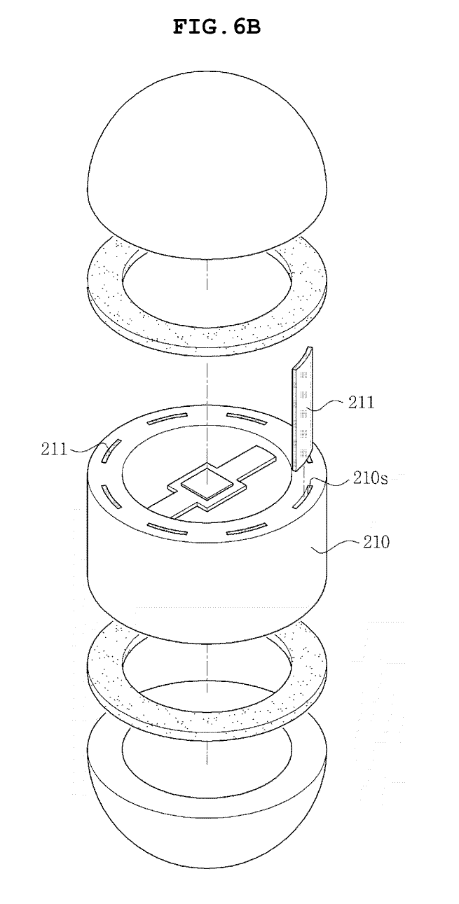

FIGS. 6a and 6b are exploded perspective views of a MEMS device package having a circular tubular part having a different type from the circular tubular part of the MEMS device package according to the second embodiment. The MEMS device package 200 shown in FIGS. 6a and 6b has a structure extremely similar to the MEMS device package of the second embodiment, except whether to include a slit 210s of the circular tubular part 210 shown in FIG. 5. Therefore, in order to assist in clear understanding of the present invention, a description of components that are the same as or similar to the above-mentioned components will be omitted.

Referring to FIGS. 6a and 6b, the circular tubular part 210 has at least one slit 210s formed on a thickness part thereof. As shown, the slit 210s is extended in a length direction of the circular tubular part 210. The circular tubular part 210 has a damper 211 inserted into the slit 210s. Here, the damper 211 may be formed of a material, for example, rubber, polymer, or the like, which can absorb an impact applied from the outside of the circular tubular part 210. Furthermore, the damper 211 may be made of foam to sufficiently fill the slit 210s to reduce porosity and maximize an impact-absorbing effect. As necessary, the damper 211 may have a honeycomb structure to become less in weight and enhance non-compressive strength.

Moreover, as shown in FIG. 6a, one slit 210s may be formed along a curve of the circular tubular part 210, and the damper 211 may be inserted into the slit corresponding to the shape of the slit. The damper 211 has the same curvature as the slit and thus may be tightly inserted and fixed.

Alternatively, as shown in FIG. 6b, a plurality of slits 210s may be formed along the curve of the circular tubular part 210. A plurality of dampers 211 may be inserted into the slits corresponding to the shape and number of the slits. Additionally, the plurality of slits 210s may be arranged at an equal distance.

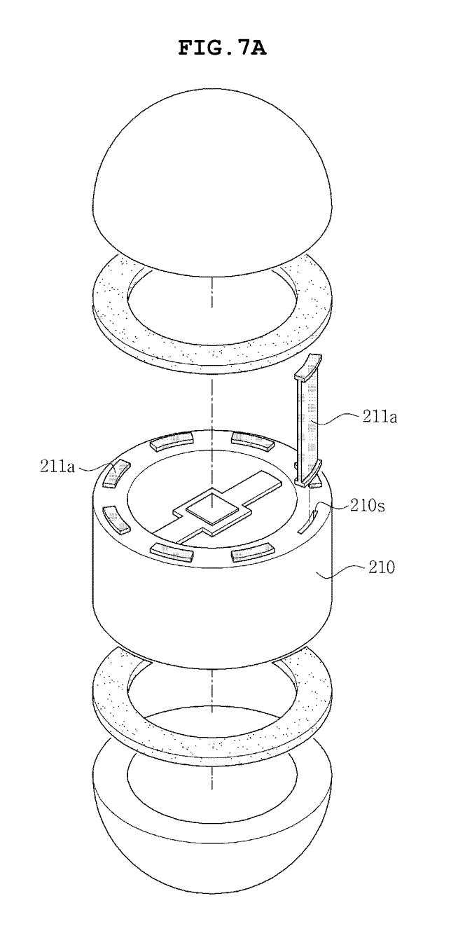

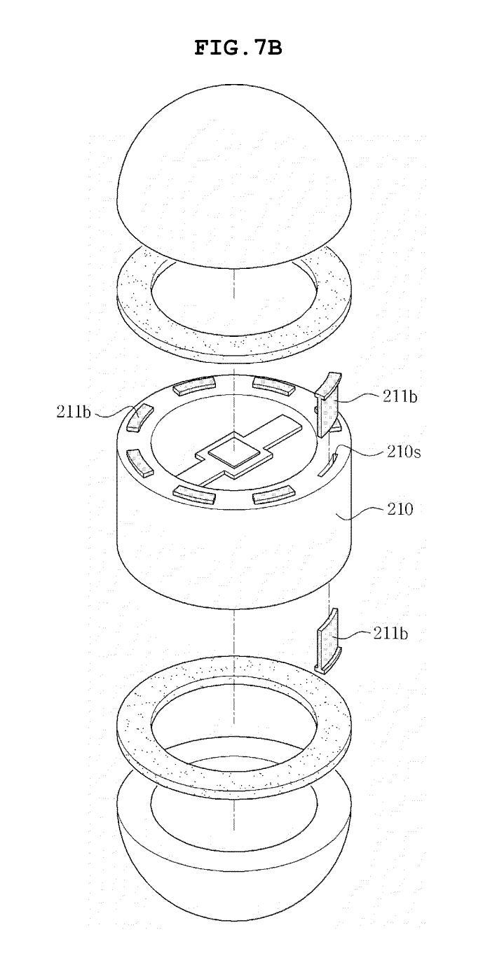

FIG. 7a is an exploded perspective view of a MEMS device package having a damper 211 a having a shape of an I-beam to be inserted to a slit of the circular tubular part 210. As shown, the damper 211a has a shape of an I-beam. A top of the damper 211a is disposed on a top surface of the circular tubular part 210, and a bottom of the damper 211a is disposed on a bottom surface of the circular tubular part 210. Since the top and bottom of the damper 211a have a size greater than the slit 110s, the damper 211a may be tightly fixed to the circular tubular part 210. The top and bottom of the damper 211a may be fitly or protrudedly arranged in the top surface and the bottom surface of the circular tubular part 210, thereby mitigating an impact applied to the top cap and/or the bottom cap, specifically an impact applied to the top and/or bottom of the MEMS device package 200 of the present invention to prevent the impact from being delivered into the circular tubular part 210.

FIG. 7b is an exploded perspective view of a MEMS device package having a damper 211b built therein. In particular, the damper 211b is formed to have a shape of a T-beam. One damper 211b may be inserted into the slit 210s formed on the top surface of the circular tubular part 210 while the other damper 21 lb may be inserted into the slit 210s formed on the bottom surface of the circular tubular part 210.

End parts of the T-beam shaped damper 211b are fitly disposed on the top and bottom surfaces of the circular tubular part 210. This will facilitate insertion into the slit 210s and secure contact to the top or bottom surface.

As set forth above, the present invention can provide a vibration proof package that may reliably guarantee a mechanical driving of an internal sensor for detecting an external movement.

The present invention can miniaturize the MEMS device package corresponding to the current trend and also sufficiently secure a mechanical driving space of an internal sensor.

In particular, the present invention may have an impact absorbing damper built in the housing of the MEMS device package, thereby protecting the internal sensor without increasing the size of the housing.

As a result, the present invention may provide the MEMS device package that can protect the internal sensor to stably operate the internal sensor in a long period of time.

Although the embodiment of the present invention has been disclosed for illustrative purposes, it will be appreciated that a MEMS device package according to the invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A MEMS device package, comprising:
a hollow tubular part;
a top cap formed to cover a top opening of the tubular part;
a bottom cap formed to cover a bottom opening of the tubular part; and
a sensor device equipped in a cavity of the tubular part.

2. The MEMS device package as set forth in claim 1, wherein the sensor device is a support structure having a plate and an elastic arm and equipped in the tubular part.

3. The MEMS device package as set forth in claim 1, wherein the tubular part has one or more slits formed along a perimeter thereof.

4. The MEMS device package as set forth in claim 3, wherein the one or more slits are separated at an equal distance along the perimeter of the tubular part.

5. The MEMS device package as set forth in claim 3, wherein the slits pass through the tubular part in a length direction.

6. The MEMS device package as set forth in claim 3, wherein a damper are inserted into each of the slits.

7. The MEMS device package as set forth in claim 6, wherein the damper has a shape of an I-beam.

8. The MEMS device package as set forth in claim 6, wherein the damper has a shape of a T-beam.

9. The MEMS device package as set forth in claim 6, wherein the damper is formed of foam.

10. The MEMS device package as set forth in claim 6, wherein the damper is formed to have a honeycomb structure.

11. The MEMS device package as set forth in claim 6, wherein the damper is curved at the same curvature as the tubular part.

12. The MEMS device package as set forth in claim 1, wherein the tubular part is a quadrangular tubular part having a quadrangular cross section.

13. The MEMS device package as set forth in claim 1, wherein the top and bottom caps are formed to have a shape of a plate.

14. The MEMS device package as set forth in claim 1, wherein the top cap has a side part protruding in a vertical direction along a perimeter thereof.

15. The MEMS device package as set forth in claim 1, wherein the bottom cap has a side part protruding in a vertical direction along a perimeter thereof.

16. The MEMS device package as set forth in claim 1, wherein the tubular part is a circular tubular part having a circular cross section.

17. The MEMS device package as set forth in claim 1, wherein the top and bottom caps are formed to have a shape of an arch.

18. The MEMS device package as set forth in claim 1, wherein adhesive layers are stacked on the top and bottom surfaces of the tubular part, respectively.
